(19) United States
(12) Patent Application Publication
(10) Pub. No.: US 2024/0364280 A1
(43) Pub. Date: Oct. 31, 2024

(54) RADIO-FREQUENCY MODULE

(71) Applicant: Murata Manufacturing Co., Ltd., Nagaokakyo-shi (JP)

(72) Inventor: Motoji TSUDA, Nagaokakyo-shi (JP)

(73) Assignee: Murata Manufacturing Co., Ltd., Nagaokakyo-shi (JP)

(21) Appl. No.: 18/765,380

(22) Filed: Jul. 8, 2024

Related U.S. Application Data
(63) Continuation of application No. PCT/JP2022/048596, filed on Dec. 28, 2022.

(30) Foreign Application Priority Data
Mar. 30, 2022 (JP) 2022-056304

(51) Int. Cl. H03F 3/195; H03F 1/26; H04B 1/3827; H04B 1/40

(52) U.S. Cl. CPC H03F 3/195; H03F 1/26; H04B 1/40; H03F 2200/294; H03F 2200/451; H04B 1/3833

(57) ABSTRACT

A radio-frequency module includes a module substrate having major surfaces that are opposite to each other, with the major surface having a recess, a first circuit component at least partially disposed within the recess, a resin member filling the recess and covering at least a portion of the first circuit component, a resin wiring layer covering the recess, and a second circuit component disposed on the resin wiring layer and electrically coupled to the first circuit component. The resin wiring layer includes a wiring portion and a resin portion that has greater strength than the resin member.

### CROSS-REFERENCE TO RELATED APPLICATIONS

This is a continuation application of PCT/JP2022/048596, filed on Dec. 28, 2022, designating the United States of America, which is based on and claims priority to Japanese Patent Application No. JP 2022-056304 filed on Mar. 30, 2022. The entire contents of the above-identified applications, including the specifications, drawings and claims, are incorporated herein by reference in their entirety.

### TECHNICAL FIELD

The present disclosure relates to radio-frequency modules.

### BACKGROUND ART

Mobile communication devices such as mobile phones have become larger, particularly due to the development of multiband operation. In Patent Document 1, integrated circuits (circuit components) are incorporated into the substrate of a radio-frequency module to miniaturize the communication device.

### CITATION LIST

### Patent Document

Patent Document 1: International Publication No. 2019/146284

### SUMMARY OF DISCLOSURE

### Technical Problem

However, further miniaturization of communication devices is desired.

The present disclosure provides radio-frequency modules that contribute to the miniaturization of communication devices.

### Solution to Problem

A radio-frequency module according to an embodiment of the present disclosure includes a module substrate having a first major surface and a second major surface that are opposite to each other, the second major surface having a recess, a first circuit component at least partially disposed within the recess, a first resin member filling the recess, a wiring layer disposed on the surface of the first resin member, made of a material different from the material of the first resin member, and a second circuit component disposed on the wiring layer. At least a portion of the first circuit component overlaps at least a portion of the second circuit component in the plan view of the module substrate.

### Advantageous Effects of Disclosure

The radio-frequency module according to an embodiment of the present disclosure contributes to the miniaturization of communication devices.

### BRIEF DESCRIPTION OF DRAWINGS

FIG. 1 is a circuit configuration diagram of a communication device according to an embodiment.

FIG. 2 is a circuit configuration diagram of a low-noise amplifier according to the embodiment.

FIG. 3 is a plan view of a radio-frequency module according to a first practical example.

FIG. 4 is a horizontal cross-sectional view of the radio-frequency module according to the first practical example.

FIG. 5 is a plan view of the radio-frequency module according to the first practical example.

FIG. 6 is a vertical sectional view of the radio-frequency module according to the first practical example.

FIG. 7 is a partial vertical sectional view of the radio-frequency module according to the first practical example.

FIG. 8 is a partial vertical sectional view of a radio-frequency module according to a modification of the first practical example.

FIG. 9 is a plan view of a radio-frequency module according to a second practical example.

FIG. 10 is a horizontal cross-sectional view of the radio-frequency module according to the second practical example.

FIG. 11 is a plan view of the radio-frequency module according to the second practical example.

FIG. 12 is a vertical sectional view of the radio-frequency module according to the second practical example.

### DESCRIPTION OF EMBODIMENTS

Hereinafter, embodiments of the present disclosure will be described in detail with reference to the drawings. The embodiments described below represent comprehensive or specific examples. Details such as numerical values, shapes, materials, constituent elements, and arrangements and connection modes of the constituent elements provided in the following embodiments are illustrative and are not intended to limit the present disclosure.

The drawings are schematically illustrated with necessary emphasis, omissions, or proportion adjustments to depict the present disclosure and do not necessarily represent exact details; thus, the shapes, positional relationships, and proportions can differ from actual implementations. Identical reference numerals are assigned to substantially the same configuration elements across the drawings, and redundant descriptions of these configuration elements can be omitted or simplified.

In the drawings described later, the x-axis and the y-axis are perpendicular to each other in a plane parallel to the major surfaces of a module substrate. Specifically, assuming the module substrate is rectangular in plan view, the x-axis is parallel to a first side of the module substrate, and the y-axis is parallel to a second side perpendicular to the first side of the module substrate. The z-axis is perpendicular to the major surfaces of the module substrate. Along the z-axis, the positive direction indicates upward, and the negative direction indicates downward.

In the circuit configurations of the present disclosure, the term “couple” applies assuming one circuit element is directly coupled to another circuit element via a connection terminal and/or an interconnect conductor. The term also applies assuming one circuit element is electrically coupled to another circuit element via still another circuit element. The term “coupled between A and B” refers to a situation in which one circuit element is positioned between A and B and coupled to both A and B. The term applies assuming the circuit element is coupled in series in the path connecting A and B and also assuming the circuit element is coupled in parallel (shunt-coupled) between the path and ground.

In the component layouts of the present disclosure, the term “plan view of a module substrate” refers to a situation in which an object is orthogonally projected onto an xy-plane and viewed from the positive side of the z-axis. The term “a sectional view of a module substrate” refers to a situation in which an object is orthogonally projected and viewed onto a yz plane along the x-axis or an xz plane along the y-axis. The expression “A overlaps B in the plan view of a module substrate” means that the region of A orthogonally projected onto an xy plane overlaps the region of B orthogonally projected onto the xy plane. The expression “A does not overlap B in the plan view of a module substrate” means that there is no region where the region of A orthogonally projected onto an xy plane overlaps the region of B orthogonally projected onto the xy plane. The expression “A is disposed between B and C” refers to a situation in which at least one of the line segments each connecting any given point within B to any given point within C passes through A. Terms describing relationships between elements, such as “parallel” and “vertical”, terms indicating an element's shape, such as “rectangular”, and numerical ranges are not meant to convey only precise meanings. These terms and numerical ranges denote meanings that are substantially the same, involving, for example, about several percent differences.

In the component layouts of the present disclosure, the expression “a component is disposed within a recess” includes not only a situation in which the component is entirely disposed within the recess but also a situation in which the component is partially disposed within the recess. The expression “a component is disposed at a major surface of a substrate” includes not only a situation in which the component is disposed in contact with the major surface of the substrate but also a situation in which the component is disposed near the major surface without making contact with the major surface (for example, assuming the component is stacked on another component that is disposed in contact with the major surface).

As used in the present disclosure, the term “transmit band” refers to a frequency band used for transmission in communication devices. The term “receive band” refers to a frequency band used for reception in communication devices. For example, in frequency division duplex (FDD) bands, different frequency bands are used as the transmit band and the receive band; in time division duplex (TDD) bands, the same frequency band is used as the transmit band and the receive band. In particular, assuming the communication devices operate as user equipment (UE) for cellular communication systems, uplink operation bands can be used as the transmit band, and downlink operation bands can be used as the receive band in FDD bands. Assuming the communication devices operate as base stations (BS) for cellular communication systems, downlink operation bands can be used as the transmit band, and uplink operation bands can be used as the receive band in FDD bands.

In the present disclosure, the term “circuit component” refers to a component that includes an active element and/or a passive element. This implies that circuit components encompass active components such as transistors and diodes, as well as passive components such as inductors, transformers, capacitors, and resistors. However, circuit components do not encompass electromechanical components such as terminals, connectors, and wires.

### Embodiment

### [1.1 Circuit Configuration of Communication Device 5]

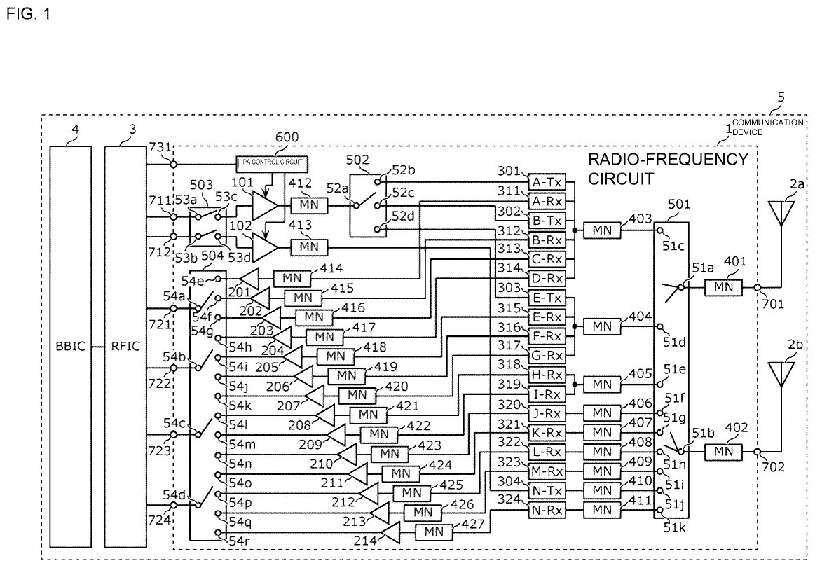

First, a circuit configuration of a communication device 5 according to an embodiment will be described with reference to FIG. 1. FIG. 1 is a circuit configuration diagram of the communication device 5 according to the present embodiment.

The communication device 5 corresponds to a UE for cellular communication systems, and is typically, for example, a mobile phone, smartphone, tablet computer, or wearable device. The communication device 5 may be an Internet of Things (IoT) sensor device, medical/health care device, automobile, unmanned aerial vehicle (UAV) (drone), or automated guided vehicle (AGV). The communication device 5 may operate as a BS for cellular communication systems.

As illustrated in FIG. 1, the communication device 5 includes a radio-frequency circuit 1, antennas 2a and 2b, a radio-frequency integrated circuit (RFIC) 3, and a baseband integrated circuit (BBIC) 4.

The radio-frequency circuit 1 is operable to transfer radio-frequency signals between the antennas 2a and 2b and the RFIC 3. The internal configuration of the radio-frequency circuit 1 will be described later.

The antennas 2a and 2b are respectively coupled to antenna connection terminals 701 and 702 of the radio-frequency circuit 1. Each of the antennas 2a and 2b is operable to transmit radio-frequency signals outputted from the radio-frequency circuit 1 and to receive radio-frequency signals from outside and output the radio-frequency signals to the radio-frequency circuit 1.

The RFIC 3 is an example of a signal processing circuit for processing radio-frequency signals. Specifically, the RFIC 3 is operable to process, for example by down-conversion, radio-frequency receive signals inputted through receive paths of the radio-frequency circuit 1 and output the receive signals generated by the signal processing to the BBIC 4. The RFIC 3 is also operable to process, for example by up-conversion, transmit signals inputted from the BBIC 4 and output the radio-frequency transmit signals generated by the signal processing to transmit paths of the radio-frequency circuit 1. The RFIC 3 includes a control unit for controlling elements included in the radio-frequency circuit 1, such as switches and amplifiers. The function of the control unit of the RFIC 3 may be partially or entirely implemented outside the RFIC 3; for example, the function of the control unit of the RFIC 3 may be implemented in the BBIC 4 and/or the radio-frequency circuit 1.

The BBIC 4 is a baseband signal processing circuit designed to perform signal processing using an intermediate frequency band that is lower than radio-frequency signals transferred by the radio-frequency circuit 1. Signals such as image signals for image display and/or sound signals for calls through speakers are used as signals to be processed by the BBIC 4.

The antennas 2a and 2b and the BBIC 4 are non-essential constituent elements in the communication device 5 according to the present embodiment.

### [1.2 Circuit Configuration of Radio-Frequency Circuit 1]

Next, a circuit configuration of the radio-frequency circuit 1 will be described with reference to FIG. 1. As illustrated in FIG. 1, the radio-frequency circuit 1 includes power amplifiers 101 and 102, low-noise amplifiers 201 to 214, filters 301 to 304 and 311 to 324, matching circuits (MNs) 401 to 427, switches 501 to 504, a PA control circuit 600, the antenna connection terminals 701 and 702, radio-frequency input terminals 711 and 712, radio-frequency output terminals 721 to 724, and a control terminal 731. In the following, the constituent elements of the radio-frequency circuit 1 will be individually described.

The antenna connection terminals 701 and 702 are respectively coupled to the antennas 2a and 2b outside the radio-frequency circuit 1. The antenna connection terminals 701 and 702 are respectively coupled to the matching circuits 401 and 402 inside the radio-frequency circuit 1.

The radio-frequency input terminals 711 and 712 are terminals for receiving radio-frequency transmit signals from outside the radio-frequency circuit 1. In FIG. 1, the radio-frequency input terminals 711 and 712 are coupled to the RFIC 3 outside the radio-frequency circuit 1 and to the switch 503 inside the radio-frequency circuit 1.

The radio-frequency output terminals 721 to 724 are terminals for supplying radio-frequency receive signals to outside the radio-frequency circuit 1. In FIG. 1, the radio-frequency output terminals 721 to 724 are coupled to the RFIC 3 outside the radio-frequency circuit 1 and to the switch 504 inside the radio-frequency circuit 1.

The control terminal 731 is a terminal for transferring control signals. Specifically, the control terminal 731 functions as a terminal for receiving control signals from outside the radio-frequency circuit 1 and/or a terminal for supplying control signals to outside the radio-frequency circuit 1. The control signal is a signal designed to control the active elements included in the radio-frequency circuit 1. In FIG. 1, the radio-frequency circuit 1 is able to receive digital signals for controlling the power amplifiers 101 and 102 from the RFIC 3 through the control terminal 731.

The power amplifiers 101 and 102 are active circuits designed to obtain output signals with higher energy than input signals (transmit signals), using power supplied from a power supply. Each of the power amplifiers 101 and 102 includes an amplifier transistor. Each of the power amplifiers 101 and 102 may additionally include an inductor and/or a capacitor. The internal configuration of the power amplifiers 101 and 102 is not limited to a specific configuration. The power amplifiers 101 and 102 may be, for example, multistage amplifiers, differential amplifiers, or Doherty amplifiers.

The power amplifier 101 is coupled between the radio-frequency input terminals 711 and 712 and the filters 301 to 303. The power amplifier 101 is designed to amplify transmit signals in bands A, B, and E. Specifically, the input terminal of the power amplifier 101 is able to be coupled to the radio-frequency input terminals 711 and 712 via the switch 503. The output terminal of the power amplifier 101 is able to be coupled to the filters 301 to 303 via the matching circuit 412 and the switch 502.

The power amplifier 102 is coupled between the radio-frequency input terminals 711 and 712 and the filter 304. The power amplifier 102 is designed to amplify transmit signals in a band N. Specifically, the input terminal of the power amplifier 102 is able to be coupled to the radio-frequency input terminals 711 and 712 via the switch 503. The output terminal of the power amplifier 102 is coupled to the filter 304 via the matching circuit 413.

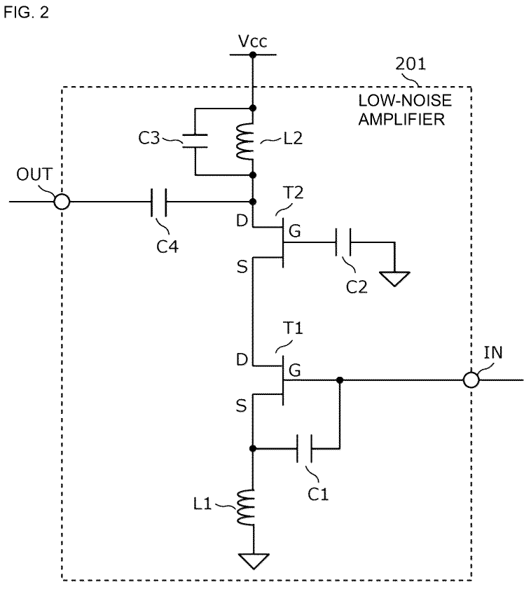

The low-noise amplifiers 201 to 214 are active circuits designed to obtain output signals with higher energy than input signals (receive signals), using power supplied from the power supply. Each of the low-noise amplifiers 201 to 214 includes an amplifier transistor. Each of the low-noise amplifiers 201 to 214 may additionally include an inductor and/or a capacitor. The internal configuration of the low-noise amplifiers 201 to 214 will be described later with reference to FIG. 2.

The low-noise amplifiers 201 to 214 are respectively coupled between the filters 311 to 324 and the radio-frequency output terminals 721 to 724. The low-noise amplifiers 201 to 214 are designed to respectively amplify receive signals in bands A to N. Specifically, the input terminals of the low-noise amplifiers 201 to 214 are respectively coupled to the filters 311 to 324 via the matching circuits 414 to 427. The output terminals of the low-noise amplifiers 201 to 214 are able to be coupled to the radio-frequency output terminals 721 to 724 via the switch 504.

In the present embodiment, one filter is coupled to one low-noise amplifier. However, this is not to be interpreted as limiting. For example, multiple filters may be coupled to one low-noise amplifier. In this case, the radio-frequency circuit may include a switch for switching the connection of the low-noise amplifier among multiple filters.

The filter 301 (A-Tx) is an example of a second filter. The filter 301 (A-Tx) has a pass band that includes a transmit band of the band A. One end of the filter 301 is able to be coupled to the output terminal of the power amplifier 101 via the switch 502 and the matching circuit 412. The other end of the filter 301 is able to be coupled to the antenna connection terminals 701 and 702 via the circuit elements including the matching circuit 403 and the switch 501.

The filter 302 (B-Tx) is an example of a second filter. The filter 302 (B-Tx) has a pass band that includes a transmit band of the band B. One end of the filter 302 is able to be coupled to the output terminal of the power amplifier 101 via the switch 502 and the matching circuit 412. The other end of the filter 302 is able to be coupled to the antenna connection terminals 701 and 702 via the circuit elements including the matching circuit 403 and the switch 501.

The filter 303 (E-Tx) is an example of a second filter. The filter 303 (E-Tx) has a pass band that includes a transmit band of the band E. One end of the filter 302 is able to be coupled to the output terminal of the power amplifier 101 via the switch 502 and the matching circuit 412. The other end of the filter 303 is able to be coupled to the antenna connection terminals 701 and 702 via the circuit elements including the matching circuit 404 and the switch 501.

The filter 304 (N-Tx) is an example of a second filter. The filter 304 (N-Tx) has a pass band that includes a transmit band of the band N. One end of the filter 304 is coupled to the output terminal of the power amplifier 102 via the matching circuit 413. The other end of the filter 304 is able to be coupled to the antenna connection terminals 701 and 702 via the circuit elements including the matching circuit 410 and the switch 501.

The filter 311 (A-Rx) is an example of a first filter. The filter 311 (A-Rx) has a pass band that includes a receive band of the band A. One end of the filter 311 is coupled to the input terminal of the low-noise amplifier 201 via the matching circuit 414. The other end of the filter 311 is able to be coupled to the antenna connection terminals 701 and 702 via the circuit elements including the matching circuit 403 and the switch 501.

The filter 312 (B-Rx) is an example of a first filter. The filter 312 (B-Rx) has a pass band that includes a receive band of the band B. One end of the filter 312 is coupled to the input terminal of the low-noise amplifier 202 via the matching circuit 415. The other end of the filter 312 is able to be coupled to the antenna connection terminals 701 and 702 via the circuit elements including the matching circuit 403 and the switch 501.

The filter 313 (C-Rx) is an example of a first filter. The filter 313 (C-Rx) has a pass band that includes a receive band of the band C. One end of the filter 313 is coupled to the input terminal of the low-noise amplifier 203 via the matching circuit 416. The other end of the filter 313 is able to be coupled to the antenna connection terminals 701 and 702 via the circuit elements including the matching circuit 403 and the switch 501.

The filter 314 (D-Rx) is an example of a first filter. The filter 314 (D-Rx) has a pass band that includes a receive band of the band D. One end of the filter 314 is coupled to the input terminal of the low-noise amplifier 204 via the matching circuit 417. The other end of the filter 314 is able to be coupled to the antenna connection terminals 701 and 702 via the circuit elements including the matching circuit 403 and the switch 501.

The filter 315 (E-Rx) is an example of a first filter. The filter 315 (E-Rx) has a pass band that includes a receive band of the band E. One end of the filter 315 is coupled to the input terminal of the low-noise amplifier 205 via the matching circuit 418. The other end of the filter 315 is able to be coupled to the antenna connection terminals 701 and 702 via the circuit elements including the matching circuit 404 and the switch 501.

The filter 316 (F-Rx) is an example of a first filter. The filter 316 (F-Rx) has a pass band that includes a receive band of the band F. One end of the filter 316 is coupled to the input terminal of the low-noise amplifier 206 via the matching circuit 419. The other end of the filter 316 is able to be coupled to the antenna connection terminals 701 and 702 via the circuit elements including the matching circuit 404 and the switch 501.

The filter 317 (G-Rx) is an example of a first filter. The filter 317 (G-Rx) has a pass band that includes a receive band of the band G. One end of the filter 317 is coupled to the input terminal of the low-noise amplifier 207 via the matching circuit 420. The other end of the filter 317 is able to be coupled to the antenna connection terminals 701 and 702 via the circuit elements including the matching circuit 404 and the switch 501.

The filter 318 (H-Rx) has a pass band that includes a receive band of the band H. One end of the filter 318 is coupled to the input terminal of the low-noise amplifier 208 via the matching circuit 421. The other end of the filter 318 is able to be coupled to the antenna connection terminals 701 and 702 via the circuit elements including the matching circuit 405 and the switch 501.

The filter 319 (I-Rx) has a pass band that includes a receive band of the band I. One end of the filter 319 is coupled to the input terminal of the low-noise amplifier 209 via the matching circuit 422. The other end of the filter 319 is able to be coupled to the antenna connection terminals 701 and 702 via the circuit elements including the matching circuit 405 and the switch 501.

The filter 320 (J-Rx) is an example of a first filter. The filter 320 (J-Rx) has a pass band that includes a receive band of the band J. One end of the filter 320 is coupled to the input terminal of the low-noise amplifier 210 via the matching circuit 423. The other end of the filter 320 is able to be coupled to the antenna connection terminals 701 and 702 via the circuit elements including the matching circuit 406 and the switch 501.

The filter 321 (K-Rx) is an example of a first filter. The filter 321 (K-Rx) has a pass band that includes a receive band of the band K. One end of the filter 321 is coupled to the input terminal of the low-noise amplifier 211 via the matching circuit 424. The other end of the filter 321 is able to be coupled to the antenna connection terminals 701 and 702 via the circuit elements including the matching circuit 407 and the switch 501.

The filter 322 (L-Rx) is an example of a first filter. The filter 322 (L-Rx) has a pass band that includes a receive band of the band L. One end of the filter 322 is coupled to the input terminal of the low-noise amplifier 212 via the matching circuit 425. The other end of the filter 322 is able to be coupled to the antenna connection terminals 701 and 702 via the circuit elements including the matching circuit 408 and the switch 501.

The filter 323 (M-Rx) has a pass band that includes a receive band of the band M. One end of the filter 323 is coupled to the input terminal of the low-noise amplifier 213 via the matching circuit 426. The other end of the filter 323 is able to be coupled to the antenna connection terminals 701 and 702 via the circuit elements including the matching circuit 409 and the switch 501.

The filter 324 (N-Rx) has a pass band that includes a receive band of the band N. One end of the filter 324 is coupled to the input terminal of the low-noise amplifier 214 via the matching circuit 427. The other end of the filter 324 is able to be coupled to the antenna connection terminals 701 and 702 via the circuit elements including the matching circuit 411 and the switch 501.

The bands A to N are frequency bands for communication systems built using a radio access technology (RAT). The bands A to N are defined by standardization organizations such as the 3rd Generation Partnership Project (3GPP)™ and the Institute of Electrical and Electronics Engineers (IEEE). Examples of the communication systems include a 5th Generation New Radio (5GNR) system, a Long-Term Evolution (LTE) system, a wireless local area network (WLAN) system, and a Global Positioning System (GPS).

In the present embodiment, LTE Bands 1, 3, 32, 40, 66, 25, 30, 34, 39, 53, 11, 21, 7, and 41 are respectively used as the bands A to N. The combination of the bands A to N is not limited to this example. For example, frequency bands for 5GNR and/or frequency bands for WLAN and GPS may be used as one, some, or all of the bands A to N.

Each of the matching circuits 401 to 427 is coupled between two circuit elements and operable to provide impedance matching between the two circuit elements. This means that the matching circuits 401 to 427 are impedance matching circuits. Each of the matching circuits 401 to 427 may include an inductor and/or a capacitor. Each of the matching circuits 401 to 427 may include a transformer.

Each of the inductors included in the matching circuits 401 to 411 is an example of a third inductor. Each of the inductors included in the matching circuits 401 to 411 is coupled between at least one of the filters 301 to 304 and 311 to 324 and the antenna connection terminals 701 and 702. Each of the inductors included in the matching circuits 412 and 413 is an example of a second inductor. Each of the inductors included in the matching circuits 412 and 413 is coupled between at least one of the filters 301 to 304 and the power amplifier 101 or 102. Each of the inductors included in the matching circuits 414 to 427 is an example of a first inductor. Each of the inductors included in the matching circuits 414 to 427 is coupled between at least one of the filters 311 to 324 and at least one of the low-noise amplifiers 201 to 214.

The switch 501 is coupled between the antenna connection terminals 701 and 702 and the filters 301 to 304 and 311 to 324. Specifically, the switch 501 has terminals 51a to 51k. The terminal 51a is coupled to the antenna connection terminal 701 via the matching circuit 401. The terminal 51b is coupled to the antenna connection terminal 702 via the matching circuit 402. The terminal 51c is coupled to the filters 301, 302, and 311 to 314 via the matching circuit 403. The terminal 51d is coupled to the filters 303 and 315 to 317 via the matching circuit 404. The terminal 51e is coupled to the filters 318 and 319 via the matching circuit 405. The terminal 51f is coupled to the filter 320 via the matching circuit 406. The terminal 51g is coupled to the filter 321 via the matching circuit 407. The terminal 51h is coupled to the filter 322 via the matching circuit 408. The terminal 51i is coupled to the filter 323 via the matching circuit 409. The terminal 51j is coupled to the filter 304 via the matching circuit 410. The terminal 51k is coupled to the filter 324 via the matching circuit 411.

With this connection configuration, the switch 501 is able to individually connect at least one of the terminals 51c to 51k to the terminal 51a and/or the terminal 51b, for example, in response to the control signal from the RFIC 3. In other words, the switch 501 is able to individually connect at least one of the filters 301 to 304 and 311 to 324 to the antenna connection terminal 701 and/or the antenna connection terminal 702. The switch 501 is implemented by a multi-connection switching circuit.

The switch 502 is coupled between the filters 301 to 303 and the power amplifier 101. Specifically, the switch 502 has terminals 52a to 52d. The terminal 52a is coupled to the output terminal of the power amplifier 101 via the matching circuit 412. The terminals 52b to 52d are respectively coupled to the filters 301 to 303.

With this connection configuration, the switch 502 is able to connect the terminal 52a to at least one of the terminals 52b to 52d, for example, in response to the control signal from the RFIC 3. In other words, the switch 502 is able to connect the power amplifier 101 to at least one of the filters 301 to 303. The switch 502 is implemented by a single-pole triple-throw (SP3T) switching circuit.

The switch 503 is coupled between the radio-frequency input terminals 711 and 712 and the power amplifiers 101 and 102. Specifically, the switch 503 has terminals 53a to 53d. The terminals 53a and 53b are respectively coupled to the radio-frequency input terminals 711 and 712. The terminals 53c and 53d are respectively coupled to the input terminals of the power amplifiers 101 and 102.

With this connection configuration, the switch 503 is able to connect the terminals 53a and 53b to the terminals 53c and 53d, for example, in response to the control signal from the RFIC 3. In other words, the switch 503 is able to connect each of the radio-frequency input terminals 711 and 712 to either the power amplifier 101 or the power amplifier 102. The switch 503 is implemented by a double-pole double-throw (DPDT) switching circuit.

The switch 504 is coupled between the radio-frequency output terminals 721 to 724 and the low-noise amplifiers 201 to 214. Specifically, the switch 504 has terminals 54a to 54r. The terminals 54a to 54d are respectively coupled to the radio-frequency output terminals 721 to 724. The terminals 54e to 54r are respectively coupled to the output terminals of the low-noise amplifiers 201 to 214.

With this connection configuration, the switch 504 is able to individually connect the terminals 54a to 54d to the terminals 54e to 54r, for example, in response to the control signal from the RFIC 3. In other words, the switch 504 is able to individually connect or disconnect the radio-frequency output terminals 721 to 724 to or from the low-noise amplifiers 201 to 214.

The PA control circuit 600 is operable to control the power amplifiers 101 and 102. For example, the PA control circuit 600 controls the bias current supplied to each of the power amplifiers 101 and 102 based on a digital control signal received from the RFIC 3 through the control terminal 731.

The circuit configuration of the radio-frequency circuit 1 in FIG. 1 is illustrative and should not be interpreted as limiting. It is sufficient for the radio-frequency circuit 1 to include at least one of the filters 311 to 324, a matching circuit coupled to the at least one of the filters 311 to 324, and a low-noise amplifier coupled to the matching circuit; other circuit elements are not necessarily included.

### [1.3 Circuit Configuration of Low-Noise Amplifier 201]

Next, a circuit configuration of the low-noise amplifier 201 will be described with reference to FIG. 2. FIG. 2 is a circuit configuration diagram of the low-noise amplifier 201 according to the present embodiment. The circuit configuration of the low-noise amplifiers 202 to 214 is the same as the circuit configuration of the low-noise amplifier 201; thus, the illustration and description will not be repeated.

As illustrated in FIG. 2, the low-noise amplifier 201 includes an input terminal IN, an output terminal OUT, cascade-connected field-effect transistors T1 and T2, inductors L1 and L2, and capacitors C1 to C4.

The input terminal IN is coupled to the filter 311 via the matching circuit 414 to receive signals in the band A.

The output terminal OUT is coupled to the terminal 54e of the switch 504 to supply amplified receive signals in the band A to one of the radio-frequency output terminals 721 to 724 through the switch 504.

The source terminal of the field-effect transistor T1 is coupled to ground via the inductor L1. The gate terminal of the field-effect transistor T1 is coupled to the input terminal IN. The drain terminal of the field-effect transistor T1 is coupled to the source terminal of the field-effect transistor T2. The capacitor C1 is coupled between the gate and the source of the field-effect transistor T1.

One end of the inductor L1 is coupled to the source terminal of the field-effect transistor T1, and the other end of the inductor L1 is coupled to ground. The inductor L1 functions as a source inductor for providing series feedback.

The source terminal of the field-effect transistor T2 is coupled to the drain terminal of the field-effect transistor T1. The gate terminal of the field-effect transistor T2 is coupled to ground via the capacitor C2. The drain terminal of the field-effect transistor T2 is coupled to the output terminal OUT via the capacitor C4. The drain terminal of the field-effect transistor T2 is also coupled to a power supply line for supplying a supply voltage through the inductor L2 and the capacitor C3, which are coupled in parallel.

One end of the inductor L2 is coupled to the drain terminal of the field-effect transistor T2, and the other end of the inductor L2 is coupled to the power supply line for supplying the supply voltage. The inductor L2 functions as a choke inductor for suppressing radio-frequency signals from flowing out of a radio-frequency signal line for transferring radio-frequency signals to the power supply line for supplying the supply voltage. The inductor L2 also functions as an impedance matching circuit for output impedance matching, in cooperation with the capacitors C3 and C4.

The circuit configuration of the low-noise amplifier 201 in FIG. 2 is illustrative and should not be interpreted as limiting. For example, heterojunction bipolar transistors may be used in place of field-effect transistors.

### First Practical Example

### [2.1 Component Layout of Radio-Frequency Module 1A]

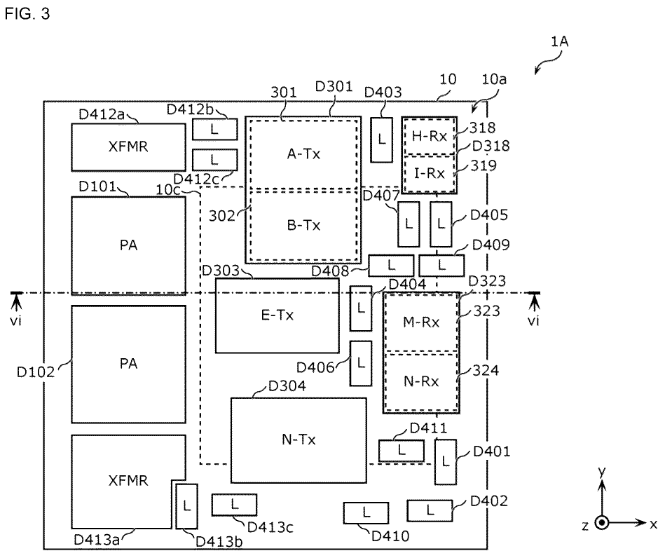

Next, a radio-frequency module 1A will be described as a first practical example of the radio-frequency circuit 1 according to the embodiment, with reference to FIGS. 3 to 7.

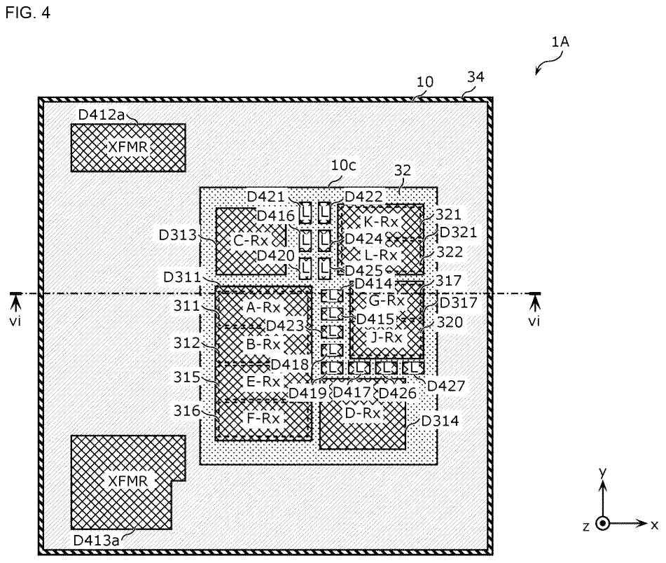

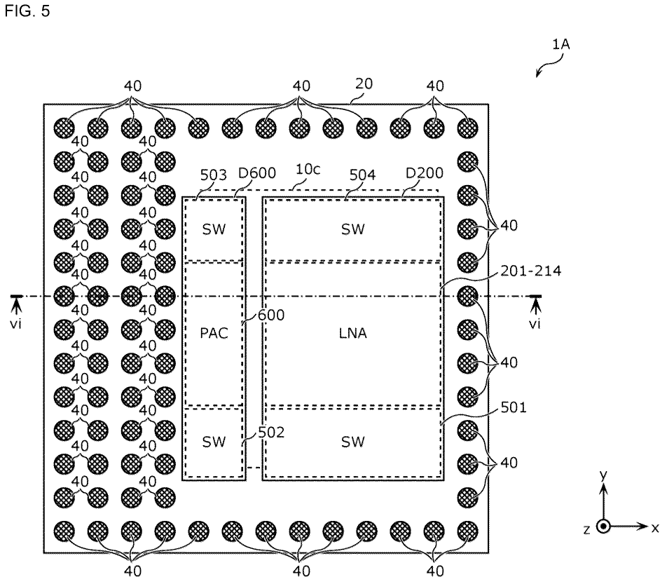

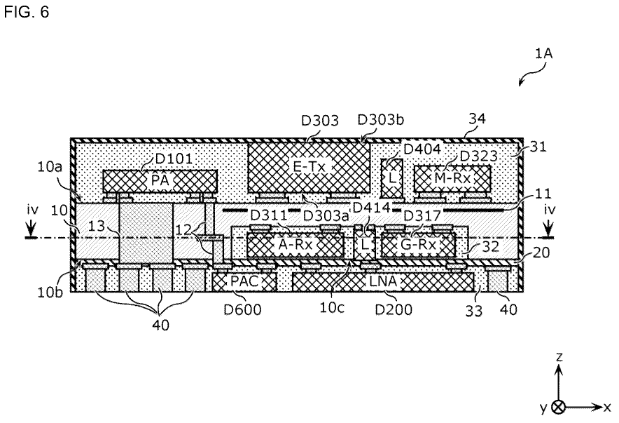

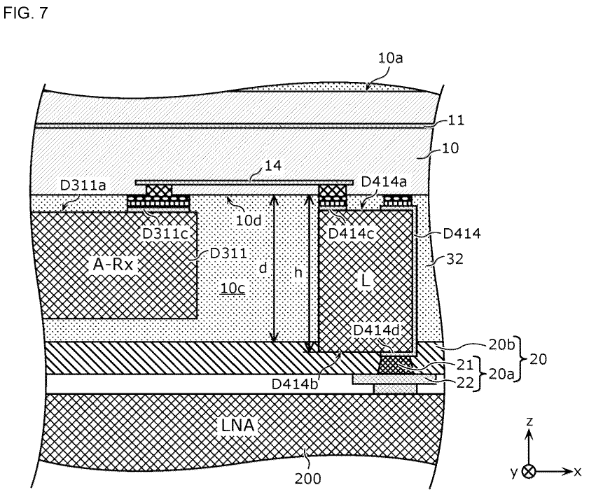

FIG. 3 is a plan view of the radio-frequency module 1A according to the present practical example. FIG. 4 is a horizontal cross-sectional view of the radio-frequency module 1A according to the present practical example. FIG. 5 is a plan view of the radio-frequency module 1A according to the present practical example, specifically a cutaway view of a major surface 10b side of a module substrate 10 from the positive side of the z-axis. FIG. 6 is a vertical sectional view of the radio-frequency module 1A according to the present practical example. FIG. 7 is a partial vertical sectional view of the radio-frequency module 1A according to the present practical example, illustrating an enlarged view of a portion around and including the matching circuit 414 in FIG. 6. The cross-section of the radio-frequency module 1A in FIG. 4 is taken along line iv-iv in FIG. 6. The section of the radio-frequency module 1A in FIG. 6 is taken along line vi-vi in FIGS. 3 to 5.

In FIGS. 3 to 7, the wires connecting circuit components disposed at the module substrate 10 are not fully illustrated. In FIGS. 3 and 5, resin members 31 and 33 that cover multiple circuit components, and a metal electrode layer 34 are not illustrated. In FIGS. 3 to 7, for ease of understanding of the positional relationship among the circuit components, the individual circuit components are sometimes assigned corresponding abbreviations (for example, “PA”) representing the function of each circuit component, although the abbreviations are not necessarily displayed in the actual circuit components.

The radio-frequency module 1A includes, as well as the circuit components that implement the circuit elements illustrated in FIG. 1, the module substrate 10, a resin wiring layer 20, resin members 31 to 33, the metal electrode layer 34, and multiple post electrodes 40.

The module substrate 10 has major surfaces 10a and 10b that are opposite to each other. The major surface 10b has a recess 10c. The major surface 10a is an example of a first major surface, and the major surface 10b is an example of a second major surface. The module substrate 10 includes a ground electrode layer 11 and via-conductors 12 and 13.

The ground electrode layer 11 is a planar electrode pattern formed within the module substrate 10 and is coupled to ground. As illustrated in FIG. 6, the ground electrode layer 11 is disposed between a chip inductor D414 and a filter component D303 in the sectional view of the module substrate 10. The ground electrode layer 11 is also disposed between a filter component D311 and the filter component D303 in the sectional view of the module substrate 10. The ground electrode layer 11 is also disposed between the filter component D311 and an integrated circuit D101 in the sectional view of the module substrate 10.

The via-conductor 12 is a conductor formed in the module substrate 10, connecting the major surfaces 10a and 10b. The via-conductor 12 can transfer signals such as radio-frequency signals or control signals. In FIG. 6, the via-conductor 12 couples an integrated circuit D600 including the PA control circuit 600 to the integrated circuit D101 including the power amplifier 101 to transfer, for example, control signals for controlling the power amplifier 101.

The via-conductor 13 is a conductor formed in the module substrate 10, connecting the major surfaces 10a and 10b. In FIG. 6, the via-conductor 13 couples the integrated circuit D101 and the post electrodes 40, functioning as a heat dissipation electrode for the integrated circuit D101.

As the module substrate 10, for example, a low temperature co-fired ceramics (LTCC) substrate or high temperature co-fired ceramics (HTCC) substrate that has a layered structure composed of multiple dielectric layers, a component-embedded substrate, a substrate including a redistribution layer (RDL), or a printed-circuit board can be used. However, these are not to be interpreted as limiting.

Each of the two integrated circuits D101 and D102, respectively including the power amplifiers 101 and 102 (PA), is an example of a seventh circuit component. The integrated circuits D101 and D102 are disposed on the major surface 10a as illustrated in FIG. 3. These integrated circuits D101 and D102 may be made of, for example, at least one of gallium arsenide (GaAs), silicon germanium (SiGe), and gallium nitride (GaN). The integrated circuits may be partially constructed using, for example, complementary metal oxide semiconductor (CMOS). Specifically, the integrated circuits may be produced through a silicon on insulator (SOI) process.

The filter component D303, which includes the filter 303 (E-Tx), is an example of a fifth circuit component. The filter component D303 is disposed on the major surface 10a as illustrated in FIG. 3. The filter component D303 overlaps a portion of the recess 10c formed at the major surface 10b side in the plan view of the module substrate 10. The filter component D303 has major surfaces D303a and D303b that are opposite to each other, as illustrated in FIG. 6. The major surface D303a is an example of a fifth major surface. The major surface D303a faces the major surface 10a of the module substrate 10. The major surface D303b is an example of a sixth major surface. The major surface D303b is in contact with the metal electrode layer 34. However, the major surface D303b is not necessarily in contact with the metal electrode layer 34. Alternatively, a portion of the major surface D303b may be in contact with the metal electrode layer 34.

Each of the filter component D301, which includes the filters 301 (A-Tx) and 302 (B-Tx), and the filter component D304, which includes the filter 304 (N-Tx), is also an example of a fifth circuit component. The filter components D301 and D304 are disposed on the major surface 10a as illustrated in FIG. 3. A portion of each of the filter components D301 and D304 overlaps a portion of the recess 10c formed at the major surface 10b side in the plan view of the module substrate 10. Although not illustrated, the filter components D301 and D304 may also be disposed to contact the metal electrode layer 34, similar to the filter component D303.

A filter component D318 including the filters 318 (H-Rx) and 319 (I-Rx) and a filter component D323 including the filters 323 (M-Rx) and 324 (N-Rx) are disposed on the major surface 10a as illustrated in FIG. 3.

These filter components D301, D303, D304, D318, and D323 may be formed by, but not limited to, for example, surface acoustic wave (SAW) filters, bulk acoustic wave (BAW) filters, LC resonance filters, or dielectric filters.

Chip inductors D401 to D411, D412b, D412c, D413b, and D413c are disposed on the major surface 10a as illustrated in FIG. 3. The chip inductors are surface mount devices (SMDs) that include inductors. Each of the chip inductors D401 to D411 is an example of a fourth circuit component. The chip inductors D401 to D411 respectively include inductors (L) included in the matching circuits 401 to 411. The chip inductors D412b and D412c are an example of a third circuit component. Each of the chip inductors D412b and D412c includes one of the two inductors (L) included in the matching circuit 412. The chip inductors D413b and D413c are also an example of a third circuit component. Each of the chip inductors D413b and D413c includes one of the two inductors (L) included in the matching circuit 413.

Two transformers (XFMR) D412a and D413a respectively included in the matching circuits 412 and 413 are disposed on the major surface 10a as illustrated in FIG. 3. For example, the primary coils included in the transformers D412a and D413a are formed by wiring patterns on the major surface 10a.

The resin member 31 is an example of a second resin member. The resin member 31 covers the major surface 10a and the circuit components on the major surface 10a as illustrated in FIG. 6. As the material of the resin member 31, for example, epoxy resin can be used. The material of the resin member 31 is not limited to epoxy resin. The resin member 31 functions to secure the reliability of mechanical strength, moisture resistance, and other properties of the circuit components disposed on the major surface 10a. However, the resin member 31 is not necessarily included in the radio-frequency module 1A.

The metal electrode layer 34 is, for example, a metal thin film formed by sputtering. As the material of the metal thin film, for example, stainless steel or copper (Cu) can be used. However, this is not to be interpreted as limiting. The metal electrode layer 34 is formed to cover the surfaces (top and side surfaces) of the resin member 31. The metal electrode layer 34 is coupled to ground and functions as a shield electrode. This implies that the metal electrode layer 34 suppresses foreign noise from entering the circuit components included in the radio-frequency module 1A and also noise generated in the radio-frequency module 1A from interfering with other modules or devices. However, the metal electrode layer 34 is not necessarily included in the radio-frequency module 1A.

The filter component D311, which includes the filters 311, 312, 315, and 316, is an example of a sixth circuit component. The filter component D311 is disposed within the recess 10c as illustrated in FIG. 4. The filter component D311 has a major surface D311a and an electrode D311c as illustrated in FIG. 7. The major surface D311a is an example of a seventh major surface. The major surface D311a faces a bottom surface 10d of the recess 10c. The electrode D311c is an example of a third electrode. The electrode D311c is disposed on the major surface D311a.

Each of a filter component D313 including the filter 313, a filter component D314 including the filter 314, a filter component D317 including the filters 317 and 320, and a filter component D321 including the filters 321 and 322 is also an example of a sixth circuit components. The filter components D313, D314, D317, and D321 are disposed within the recess 10c as illustrated in FIG. 4. Although not illustrated, the filter components D313, D314, D317, and D321 also have electrodes on the major surfaces facing the bottom surface 10d of the recess 10c, similar to the filter component D311. At least a portion of the filter component D313 overlaps at least a portion of the filter component D301 in the plan view of the module substrate 10.

These filter components D311, D313, D314, D317, and D321 may be formed by, but not limited to, for example, SAW filters, BAW filters, LC resonance filters, or dielectric filters.

Each of chip inductors D414 to D427 is an example of a first circuit component. The chip inductors D414 to D427 are disposed within the recess 10c as illustrated in FIG. 4. The chip inductors D414 to D427 respectively include inductors (L) included in the matching circuits 414 to 427. At least a portion of the chip inductors D414 to D427 overlaps at least a portion of the filter components D301 and D303 and also overlaps at least a portion of an integrated circuit D200, which will be described later, in the plan view of the module substrate 10. Each of the chip inductors D414 to D427 does not overlap the chip inductors D401 to D411, D412b, D412c, D413b, and D413c in the plan view of the module substrate 10.

As illustrated in FIG. 7, the chip inductor D414 has major surfaces D414a and D414b that are opposite to each other, and electrodes D414c and D414d. The major surface D414a is an example of a third major surface. The major surface D414a faces the bottom surface 10d of the recess 10c. The major surface D414b is an example of a fourth major surface.

A height h of the chip inductor D414 is greater than a depth d of the recess 10c. Thus, an end portion (the major surface D414b) of the chip inductor D414 is inserted into a recess in the resin wiring layer 20. The height h of the chip inductor D414 is specified by measuring the distance along the z-axis from the bottom surface 10d of the recess 10c, where the chip inductor D414 is disposed, to the major surface D414b in the sectional view of the module substrate 10. The depth d of the recess 10c is specified by measuring the distance along the z-axis from the bottom surface 10d of the recess 10c to the major surface 10b of the module substrate 10 in the sectional view of the module substrate 10.

The electrode D414c is an example of a first electrode. The electrode D414c is disposed on the major surface D414a. The electrode D414c is electrically coupled to the electrode D311c of the filter component D311 via a wire 14 in the module substrate 10.

The electrode D414d is an example of a second electrode. The electrode D414d is disposed on the major surface D414b. The electrode D414d is electrically coupled to the integrated circuit D200 via a via-conductor 21 in the resin wiring layer 20.

Although not illustrated, the chip inductors D415 to D427 may also have electrodes respectively disposed on the opposite major surfaces, similar to the chip inductor D414.

The resin member 32 is an example of a first resin member. The resin member 32 fills the recess 10c as illustrated in FIGS. 4 and 6. As the material of the resin member 32, for example, epoxy resin can be used. The material of the resin member 32 is not limited to epoxy resin. The resin member 32 functions to secure the reliability of mechanical strength, moisture resistance, and other properties of the circuit components disposed within the recess 10c.

The resin wiring layer 20 covers the recess 10c. In the present practical example, the resin wiring layer 20 is disposed on a surface of the resin member 32. In other words, the resin wiring layer 20 covers at least a portion of the surfaces of the resin member 32. In the present practical example, the resin wiring layer 20 also covers the major surface 10b of the module substrate 10.

As illustrated in FIG. 7, the resin wiring layer 20 includes a wiring portion 20a and a resin portion 20b. The wiring portion 20a includes the via-conductor 21, a land electrode 22, and wiring patterns that are not illustrated. The resin portion 20b is made of a material different from the resin member 32 and has a higher strength than the resin member 32. For example, polyimide can be used as the material of the resin portion 20b. The material of the resin portion 20b is not limited to polyimide.

The strength of a resin member is defined by the tensile elasticity modulus, or Young's modulus (longitudinal tensile modulus). The greater the tensile elasticity modulus, the greater the strength of the resin member. Thus, the condition in which the strength of the resin portion 20b is higher than the strength of the resin member 32 means that the tensile elasticity modulus of the resin portion 20b is higher than the tensile elasticity modulus of the resin member 32.

Each of the integrated circuit D200, which includes the low-noise amplifiers 201 to 214 (LNA) and the switches 501 and 504 (SW), and the integrated circuit D600, which includes the PA control circuit 600 (PAC) and the switches 502 and 503, is an example of a second circuit component. The integrated circuits D200 and D600 are disposed on the resin wiring layer 20 as illustrated in FIG. 5. The integrated circuits D200 and D600 are constructed using, for example, CMOS. Specifically, The integrated circuits D200 and D600 are produced through an SOI process. The integrated circuits D200 and D600 are not limited to CMOS components.

The post electrodes 40 function serve as external connection terminals including the antenna connection terminals 701 and 702, the radio-frequency input terminals 711 and 712, the radio-frequency output terminals 721 to 724, and the control terminal 731, which are illustrated in FIG. 1, and ground terminals not illustrated in FIG. 1. The individual post electrodes 40 can be coupled to terminals including, for example, input-output terminals and/or ground terminals at a mother substrate (not illustrated) positioned on the negative side of the z-axis with respect to the radio-frequency module 1A. Copper electrodes can be used as the post electrodes 40. However, this is not to be interpreted as limiting. For example, multiple solder or nickel silver electrodes may be used as the post electrodes 40. Multiple bump electrodes may be used in place of the post electrodes 40.

The resin member 33 covers the resin wiring layer 20 and the circuit components on the resin wiring layer 20 as illustrated in FIG. 6. As the material of the resin member 33, for example, epoxy resin can be used. The material of the resin member 33 is not limited to epoxy resin. The resin member 33 functions to secure the reliability of mechanical strength, moisture resistance, and other properties of the circuit components disposed on the resin wiring layer 20. However, the resin member 33 is not necessarily included in the radio-frequency module 1A.

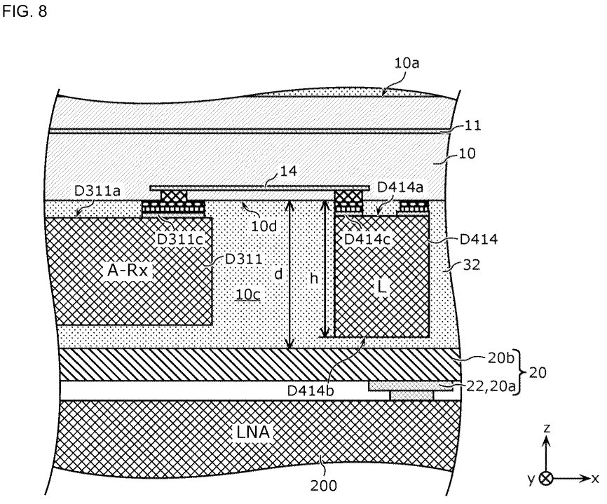

The configuration of the radio-frequency module 1A in FIGS. 3 to 7 is illustrative and should not be interpreted as limiting. For example, in FIGS. 6 and 7, the chip inductor D414 has the electrode D414c disposed on the major surface D414a and the electrode D414d disposed on the major surface D414b; However, as illustrated in FIG. 8, the chip inductor D414 may have either one of the electrodes D414c and D414d. Further, as illustrated in FIG. 8, the height h of the chip inductor D414 may be smaller than the depth d of the recess 10c.

### [2.2 Effects]

As described above, the radio-frequency module 1A according to the present practical example includes the module substrate 10 having the major surfaces 10a and 10b that are opposite to each other, with the major surface 10b having the recess 10c, a first circuit component (for example, chip inductors D414 to D427) at least partially disposed within the recess 10c, the resin member 32 filling the recess 10c and covering at least a portion of the first circuit component, the resin wiring layer 20 covering the recess 10c, and a second circuit component (for example, the integrated circuit D200 or D600) disposed on the resin wiring layer 20 and electrically coupled to the first circuit component. The resin wiring layer 20 includes the wiring portion 20a and the resin portion 20b that has greater strength than the resin member 32.

In another aspect, the radio-frequency module 1A according to the present practical example includes the module substrate 10 having the major surfaces 10a and 10b that are opposite to each other, with the major surface 10b having the recess 10c, a first circuit component (for example, the chip inductors D414 to D427) at least partially disposed within the recess 10c, an epoxy resin member (the resin member 32) filling the recess 10c and covering at least a portion of the first circuit component, the resin wiring layer 20 covering the recess 10c and having a polyimide resin portion (the resin portion 20b) and the wiring portion 20a, and a second circuit component (for example, the integrated circuit D200 or D600) disposed on the resin wiring layer 20 and electrically coupled to the first circuit component.

In this configuration, the first circuit component is disposed within the recess 10c of the module substrate 10, and the second circuit component is disposed on the resin wiring layer 20 that covers the recess 10c. This configuration effectively utilizes the areas inside and above the recess 10c, thereby achieving the miniaturization of the radio-frequency module 1A and consequently contributing to the miniaturization of the communication device 5. Furthermore, disposing the first circuit component within the recess 10c reduces the failure rate of the first circuit component compared to integrating the first circuit component into the module substrate 10 through pressing of the module substrate 10. In particular, the recess 10c is covered by the resin wiring layer 20 that includes the resin portion 20b (the polyimide resin portion) having greater strength than the resin member 32 (the epoxy resin member). This configuration improves the mechanical strength of the first circuit component disposed within the recess 10c during or after the production of the radio-frequency module 1A, thereby further reducing the failure rate of the first circuit component.

In an example, in the radio-frequency module 1A according to the present practical example, the first circuit component may be the chip inductors D414 to D427 including inductors that constitute the matching circuits 414 to 427 coupled between the filters 311 to 324 and the low-noise amplifiers 201 to 214.

In this configuration, the inductors coupled to the receive paths are disposed within the recess 10c. This configuration easily hinders coupling with the other inductors coupled to the transmit paths, thereby suppressing the decrease in receive sensitivity.

In an example, in the radio-frequency module 1A according to the present practical example, the chip inductor D414 may have the major surfaces D414a and D414b that are opposite to each other, the major surface D414a may face the bottom surface 10d of the recess 10c, and the chip inductor D414 may further include the electrode D414c disposed on the major surface D414a and the electrode D414d disposed on the major surface D414b.

In this configuration, the electrodes D414c and D414d are disposed on both the major surfaces D414a and D414b of the chip inductor D414. This configuration shortens the length of wires coupling the circuit components disposed on the major surface 10a or within the recess 10c to the circuit components disposed on the resin wiring layer 20, thereby reducing mismatch loss due to wiring loss and wiring variation, and consequently improving the electrical characteristics of the radio-frequency module 1A.

In an example, in the radio-frequency module 1A according to the present practical example, the height h of the chip inductor D414 may be greater than the depth d of the recess 10c.

In this configuration, the height h of the chip inductor D414 disposed within the recess 10c is greater than the depth d of the recess 10c. This configuration reduces the depth d of the recess 10c, thereby suppressing the increase in the thickness of the module substrate 10 that can result from incorporating the recess 10c.

In an example, the radio-frequency module 1A according to the present practical example may further include the chip inductor D412b, D412c, D413b, or D413c disposed on the major surface 10a, constituting the matching circuit 412 or 413 coupled between the power amplifier 101 or 102 and the filters 301 to 304. It may also be possible that the chip inductors D414 to D427 do not overlap the chip inductors D412b, D412c, D413b, and D413c in the plan view of the module substrate 10.

In this configuration, the chip inductors D414 to D427 disposed within the recess 10c do not overlap the chip inductors D412b, D412c, D413b, or D413c disposed on the major surface 10a. This configuration hinders coupling of the chip inductors D414 to D427 with the chip inductors D412b, D412c, D413b, or D413c, thereby improving the electrical characteristics of the radio-frequency module 1A.

In an example, the radio-frequency module 1A according to the present practical example may further include the chip inductors D401 to D411 disposed on the major surface 10a, constituting the matching circuits 401 to 411 coupled between the filters 311 to 324 and the antenna connection terminal 701 or 702. It may also be possible that the chip inductors D414 to D427 do not overlap the chip inductors D401 to D411 in the plan view of the module substrate 10.

In this configuration, the chip inductors D414 to D427 disposed within the recess 10c do not overlap the chip inductors D401 to D411 disposed on the major surface 10a. This configuration hinders coupling of the chip inductors D414 to D427 with the chip inductors D401 to D411, thereby improving the electrical characteristics of the radio-frequency module 1A.

In an example, in the radio-frequency module 1A according to the present practical example, the second circuit component may be the integrated circuit D200 including the low-noise amplifiers 201 to 214.

In this configuration, the integrated circuit D200 including the low-noise amplifiers 201 to 214 is disposed on the resin wiring layer 20 (under the recess 10c). This configuration positions the inductor (for example, the inductor L1 and/or the inductor L2 in FIG. 2) included in the integrated circuit D200 away from the wire (for example, the ground electrode layer 11) in the module substrate 10, thereby suppressing deterioration of the characteristics of the inductor included in the integrated circuit D200.

In an example, the radio-frequency module 1A according to the present practical example may further include a fifth circuit component (for example, the filter component D301, D303, or D304) disposed on the major surface 10a. At least a portion of the first circuit component may overlap at least a portion of the fifth circuit component in the plan view of the module substrate 10.

In this configuration, since the fifth circuit component is disposed on the major surface 10a of the module substrate 10, multiple circuit components can be disposed on the major surface 10a side of the module substrate 10, inside the module substrate 10, and on the major surface 10b side of the module substrate 10. This configuration achieves further miniaturization of the radio-frequency module 1A, thereby contributing to the miniaturization of the communication device 5.

In an example, in the radio-frequency module 1A according to the present practical example, the fifth circuit component may be the filter component D301, D303, or D304 including the filters 301 to 304 coupled to the power amplifier 101 or 102.

With this configuration, multiple circuit components can be disposed on the major surface 10a side of the module substrate 10, inside the module substrate 10, and on the major surface 10b side of the module substrate 10 in a well-balanced manner.

In an example, in the radio-frequency module 1A according to the present practical example, the module substrate 10 may include the ground electrode layer 11 disposed between the chip inductors D414 to D427 and the filter components D301, D303, or D304 in the sectional view of the module substrate 10.

Since in this configuration the ground electrode layer 11 is disposed between the chip inductors D414 to D427 and the filter components D301, D303, or D304, the coupling between the chip inductors D414 to D427 and the filter components D301, D303, or D304 can be hindered. This configuration enhances the isolation between the transmit paths and the receive paths, thereby improving the electrical characteristics of the radio-frequency module 1A.

In an example, the radio-frequency module 1A according to the present practical example may further include the resin member 31 covering at least a portion of the major surface 10a and at least a portion of the filter component D303, and the metal electrode layer 34 covering at least a portion of a surface of the resin member 31. The filter component D303 may have the major surfaces D303a and D303b that are opposite to each other. The major surface D303a may face the major surface 10a of the module substrate 10, and at least a portion of the major surface D303b may be in contact with the metal electrode layer 34.

Since the filter component D303 is in contact with the metal electrode layer 34, this configuration improves the heat dissipation capability of the filter component D303. In particular, the filter component D303 including the filter 303 for passing transmit signals generates more heat than filters for passing receive signals. Thus, the effect of improving the heat dissipation capability is greater in the filter component D303.

In an example, the radio-frequency module 1A according to the present practical example may further include a sixth circuit component (for example, the filter component D311, D313, D314, D317, or D321) at least partially disposed within the recess 10c.

Since the sixth circuit component is disposed within the recess 10c in addition to the first circuit component, this configuration achieves further miniaturization of the radio-frequency module 1A.

In an example, in the radio-frequency module 1A according to the present practical example, the sixth circuit component may be the filter component D311, D313, D314, D317, or D321 including the filters 311 to 317 and 320 to 322.

With this configuration, multiple circuit components can be disposed on the major surface 10a side of the module substrate 10, inside the module substrate 10, and on the major surface 10b side of the module substrate 10 in a well-balanced manner. Additionally, the circuit components including circuit elements coupled to the receive paths can be disposed within the recess 10c. This configuration enhances the isolation between the transmit paths and the receive paths, thereby improving the electrical characteristics of the radio-frequency module 1A.

In an example, in the radio-frequency module 1A according to the present practical example, the filter component D311, D313, D314, D317, or D321 may have the major surface D311a, which faces the bottom surface 10d of the recess 10c, and the electrode D311c disposed on the major surface D311a.

In this configuration, the filter components D311, D313, D314, D317, or D321 can be coupled to the bottom surface 10d of the recess 10c instead of the resin wiring layer 20. This configuration positions the conductive portion of the filter component D311 away from the integrated circuit D200 disposed on the resin wiring layer 20, thereby suppressing deterioration of the characteristics of the inductors included in the integrated circuit D200.

In an example, in the radio-frequency module 1A according to the present practical example, the electrode D414c of the chip inductor D414 may be electrically coupled to the electrode D311c of the filter component D311, and the electrode D414d of the chip inductor D414 may be electrically coupled to the integrated circuit D200.

In this configuration, the two electrodes D414c and D414d disposed respectively on the two major surfaces D414a and D414b of the chip inductor D414 are electrically coupled to the filter component D311 and the integrated circuit D200. Since the filter component D311 and the integrated circuit D200 include the filter 311 and the low-noise amplifier 201 that are coupled to the inductor in the chip inductor D414, this configuration more effectively shortens the wire length.

In an example, in the radio-frequency module 1A according to the present practical example, the module substrate 10 may include the via-conductor 12 connecting the major surfaces 10a and 10b, and the filter component D311 may be disposed between the chip inductor D414 and the via-conductor 12 in the plan view of the module substrate 10.

In this configuration, the filter component D311 is disposed between the chip inductor D414 and the via-conductor 12. This configuration hinders the coupling between the chip inductor D414 and the via-conductor 12, thereby improving the electrical characteristics of the radio-frequency module 1A.

In an example, the radio-frequency module 1A according to the present practical example may further include the integrated circuit D101 or D102 that is disposed on the major surface 10a and that includes the power amplifier 101 or 102. The module substrate 10 may include the ground electrode layer 11 disposed between the filter components D311, D313, D314, D317, or D321 and the integrated circuit D101 or D102 in the sectional view of the module substrate 10.

In this configuration, the ground electrode layer 11 is disposed between the filter component D311, D313, D314, D317, or D321, which includes a filter for passing receive signals, and the integrated circuit D101 or D102, which includes the power amplifier 101 or 102. This configuration hinders the coupling between the filter components D311, D313, D314, D317, or D321 and the integrated circuit D101 or D102. As a result, this configuration enhances the isolation between the transmit paths and the receive paths, thereby improving the electrical characteristics of the radio-frequency module 1A.

### Second Practical Example

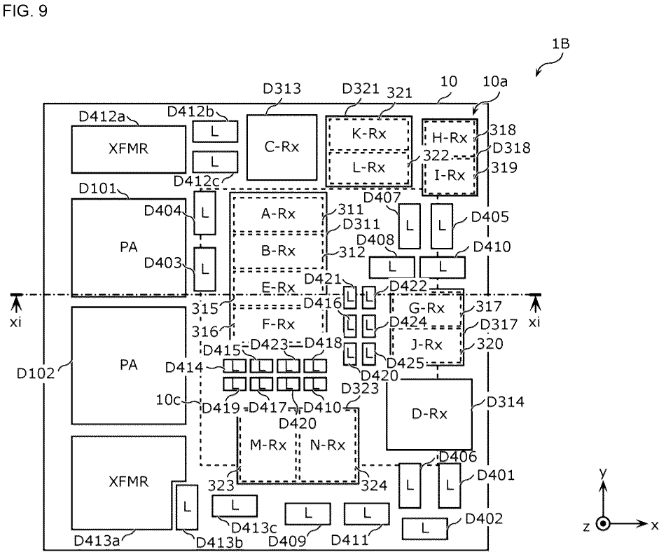

Next, a radio-frequency module 1B will be described as a second practical example of the radio-frequency circuit 1 according to the embodiment. The present practical example differs from the first practical example in the layout of circuit components, particularly in that the transmit filters are disposed within the recess in the module substrate. In the following, the radio-frequency module 1B according to the present practical example will be described with reference to FIGS. 9 to 12, focusing primarily on features that differ from the first practical example.

### [3.1 Component Layout of Radio-Frequency Module 1B]

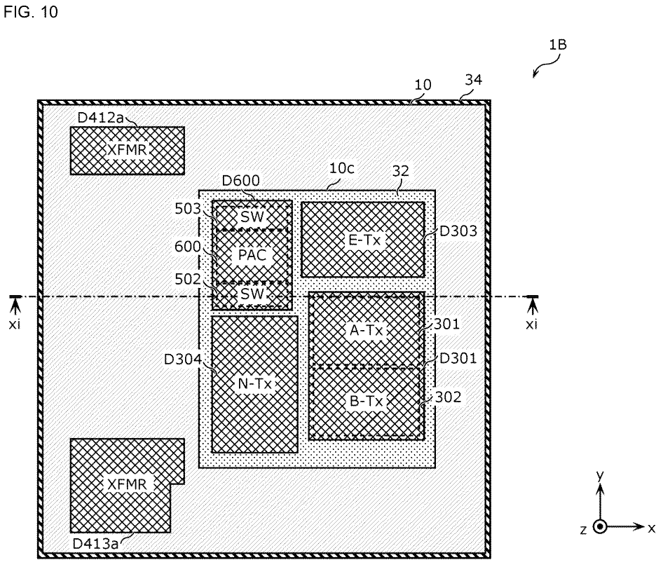

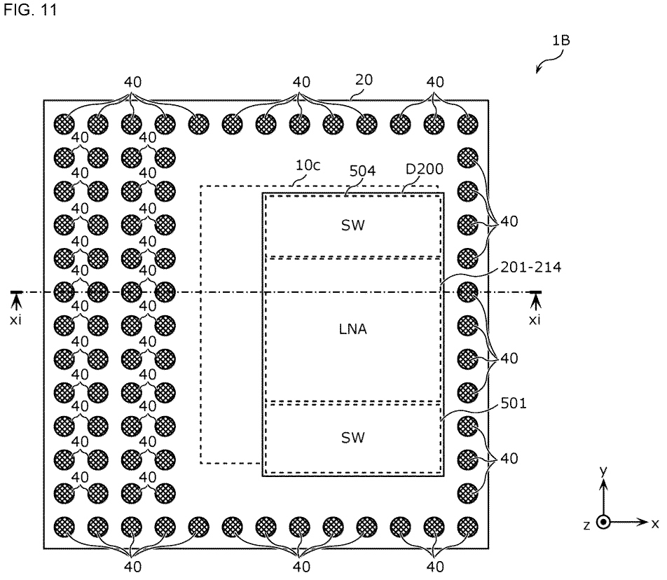

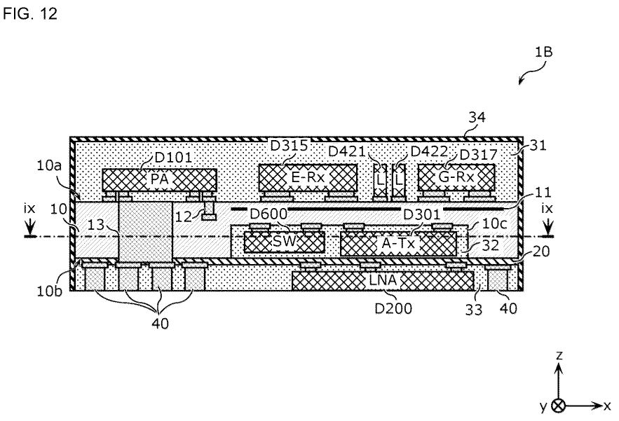

FIG. 9 is a plan view of the radio-frequency module 1B according to the present practical example. FIG. 10 is a horizontal cross-sectional view of the radio-frequency module 1B according to the present practical example. FIG. 11 is a plan view of the radio-frequency module 1B according to the present practical example, specifically a cutaway view of a surface side of a resin wiring layer 20 from the positive side of the z-axis. FIG. 12 is a vertical sectional view of the radio-frequency module 1B according to the present practical example. The cross-section of the radio-frequency module 1B in FIG. 10 is taken along line ix-ix in FIG. 12. The section of the radio-frequency module 1B in FIG. 12 is taken along line xi-xi in FIG. 9 to 11.

In FIGS. 9 to 12, the wires connecting circuit components disposed at the module substrate 10 are not fully illustrated. In FIGS. 9 and 11, resin members 31 and 33 that cover multiple circuit components, and a metal electrode layer 34 are not illustrated. In FIGS. 9 to 12, for ease of understanding of the positional relationship among the circuit components, the individual circuit components are sometimes assigned corresponding abbreviations (for example, “PA”) representing the function of each circuit component, although the abbreviations are not necessarily displayed in the actual circuit components.

In the present practical example, each of filter components D301, D303, and D304, and the integrated circuit D600 is an example of a first circuit component. The filter components D301, D303, and D304, and the integrated circuit D600 are disposed within the recess 10c as illustrated in FIG. 10. Each of filter components D311, D313, D314, D317, and D321 and chip inductors D414 to D427, which are disposed within the recess 10c in first practical example, is an example of a fifth circuit component. The filter components D311, D313, D314, D317, and D321 and the chip inductors D414 to D427 are disposed on a major surface 10a as illustrated in FIG. 9. At least a portion of the filter component D314 overlaps at least a portion of the filter component D301 in the plan view of the module substrate 10.

The configuration of the radio-frequency module 1B in FIGS. 9 to 12 is illustrative and should not be interpreted as limiting. For example, it may be possible that the integrated circuit D600 disposed within the recess 10c does not include one or two of switches 502 and 503 and a PA control circuit 600. In this case, an integrated circuit including the one or two of the switches 502 and 503 and the PA control circuit 600, which are not included in the integrated circuit D600, may be disposed on the resin wiring layer 20. The integrated circuit D600 including the switches 502 and 503 and the PA control circuit 600 is not necessarily disposed within the recess 10c, but may be disposed on the resin wiring layer 20.

### [3.2 Effects]

As described above, the radio-frequency module 1B according to the present practical example includes the module substrate 10 having the major surfaces 10a and 10b that are opposite to each other, with the major surface 10b having the recess 10c, a first circuit component (for example, the filter component D301, D303, or D304, or the integrated circuit D600) at least partially disposed within the recess 10c, the resin member 32 filling the recess 10c, the resin wiring layer 20 disposed on the surface of the resin member 32, made of a material different from the material of the resin member 32, and a second circuit component (for example, the integrated circuit D200) disposed on the resin wiring layer 20. At least a portion of the first circuit component overlaps at least a portion of the second circuit component in the plan view of the module substrate 10.

In this configuration, the first circuit component is disposed within the recess 10c of the module substrate 10, and the second circuit component is disposed on the resin wiring layer 20 that is formed at the surface of the resin member 32 filling the recess 10c. This configuration effectively utilizes the areas inside and above the recess 10c, thereby achieving the miniaturization of the radio-frequency module 1B and consequently contributing to the miniaturization of the communication device 5. Furthermore, disposing the first circuit component within the recess 10c reduces the failure rate of the first circuit component compared to integrating the first circuit component into the module substrate 10 through pressing of the module substrate 10. In particular, since the resin member 32 formed of a material different from the material of the resin wiring layer 20 fills the recess 10c, this configuration improves the mechanical strength of the first circuit component disposed within the recess 10c, thereby further reducing the failure rate of the first circuit component.

In an example, in the radio-frequency module 1B according to the present practical example, the first circuit component may be the filter component D301, D303, or D304 including the filters 301 to 304 coupled to the power amplifier 101 or 102.

In this configuration, the filter components D301, D303, or D304 is disposed within the recess 10c. This configuration enhances flexibility in positioning multiple circuit components.

In an example, in the radio-frequency module 1B according to the present practical example, the first circuit component may be the integrated circuit D600 including the switch 502 coupled between the power amplifier 101 or 102 and the filters 301 to 304.

In this configuration, the integrated circuit D600 including the switch 502 is disposed within the recess 10c. This configuration enhances flexibility in positioning multiple circuit components.

In an example, in the radio-frequency module 1B according to the present practical example, the first circuit component may be the integrated circuit D600 including the PA control circuit 600 for controlling the power amplifier 101 or 102.

In this configuration, the integrated circuit D600 including the PA control circuit 600 is disposed within the recess 10c. This configuration enhances flexibility in positioning multiple circuit components.

### Other Embodiments

The radio-frequency module according to the present disclosure has been described above based on the embodiment and practical examples. However, the radio-frequency module according to the present disclosure is not limited to the embodiment and practical examples. The present disclosure also embraces other embodiments implemented by any combination of the constituent elements of the practical examples, other modifications obtained by making various modifications that occur to those skilled in the art without departing from the scope of the embodiment and practical examples, and various hardware devices including the radio-frequency module.

For example, in the circuit configuration of the radio-frequency circuit according to the embodiment described above, other circuit elements and/or interconnections may also be inserted in the paths connecting the circuit elements and the signal paths that are illustrated in the drawings. Matching circuits may include capacitors in place of or in addition to inductors. In this case, chip capacitors are provided in place of or in addition to the chip inductors in the practical examples.

The layouts of circuit components in the practical examples are not limited to the layouts presented in the drawings. For example, one, some, or all of the circuit components disposed on the major surface 10a may be disposed on the resin wiring layer 20. For example, one, some, or all of the circuit components disposed on the resin wiring layer 20 may be disposed on the major surface 10a.

In the embodiment, the communication device 5 has transmit paths and receive paths. However, this should not be interpreted as limiting. For example, the communication device 5 may have either transmit paths or receive paths.

### INDUSTRIAL APPLICABILITY

The present disclosure can be used as a radio-frequency module provided at the front-end in a wide variety of communication devices such as mobile phones.

### REFERENCE SIGNS LIST

1 radio-frequency circuit
1A, 1B radio-frequency module
2a, 2b antenna
3 RFIC
4 BBIC
5 communication device
10 module substrate
10a, 10b, D303a, D303b, D311a, D414a, D414b major surface
10c recess
10d bottom surface
11 ground electrode layer
12, 13, 21 via-conductor
14 wire
20 resin wiring layer
20a wiring portion
20b resin portion
22 land electrode
31, 32, 33 resin member
34 metal electrode layer
40 post electrode
101, 102 power amplifier
201-214 low-noise amplifier
301-304, 311-324 filter
401-427 matching circuit
501-504 switch
600 PA control circuit
701, 702 antenna connection terminal
711, 712 radio-frequency input terminal
721-724 radio-frequency output terminal
731 control terminal
D101, D102, D200, D600 integrated circuit
D301, D303, D304, D311, D313, D314, D317, D318, D321,
D323 filter component
D311c, D414c, D414d electrode
D401-D411, D412b, D412c, D413b, D413c, D414-D427 chip inductor
D412a, D413a transformer

1. A radio-frequency module comprising:
a module substrate having a first major surface and a second major surface that are opposite to each other, the second major surface having a recess;
a first circuit component at least partially disposed within the recess;
a first resin member filling the recess, the first resin member covering at least a portion of the first circuit component;
a resin wiring layer covering the recess; and
a second circuit component disposed on the resin wiring layer, the second circuit component being electrically coupled to the first circuit component, wherein
the resin wiring layer includes a wiring portion and a resin portion that has greater strength than the first resin member.

2. The radio-frequency module according to claim 1, wherein
the first circuit component includes a first inductor coupled between a first filter and a low-noise amplifier.

3. The radio-frequency module according to claim 2, wherein
the first circuit component has a third major surface and a fourth major surface that are opposite to each other,
the third major surface faces a bottom surface of the recess, and
the first circuit component further has a first electrode disposed on the third major surface and a second electrode disposed on the fourth major surface.

4. The radio-frequency module according to claim 2, wherein
a height of the first circuit component is greater than a depth of the recess.

5. The radio-frequency module according to claim 2, further comprising:
a third circuit component disposed on the first major surface or the resin wiring layer, the third circuit component including a second inductor coupled between a power amplifier and a second filter, wherein
the first circuit component does not overlap the third circuit component in a plan view of the module substrate.

6. The radio-frequency module according to claim 2, further comprising:
a fourth circuit component disposed on the first major surface or the resin wiring layer, the fourth circuit component including a third inductor coupled between the first filter and an antenna connection terminal, wherein
the first circuit component does not overlap the fourth circuit component in a plan view of the module substrate.

7. The radio-frequency module according to claim 3, wherein
the second circuit component includes the low-noise amplifier.

8. The radio-frequency module according to claim 7, further comprising:
a fifth circuit component disposed on the first major surface, wherein
at least a portion of the first circuit component overlaps at least a portion of the fifth circuit component in a plan view of the module substrate.

9. The radio-frequency module according to claim 8, wherein
the fifth circuit component includes a second filter coupled to a power amplifier.

10. The radio-frequency module according to claim 9, wherein
the module substrate includes a ground electrode layer disposed between the first circuit component and the fifth circuit component in a sectional view of the module substrate.

11. The radio-frequency module according to claim 9, further comprising:
a second resin member covering at least a portion of the first major surface and at least a portion of the fifth circuit component; and
a metal electrode layer covering at least a portion of a surface of the second resin member, wherein
the fifth circuit component has a fifth major surface and a sixth major surface that are opposite to each other,
the fifth major surface faces the first major surface of the module substrate, and
at least a portion of the sixth major surface is in contact with the metal electrode layer.

12. The radio-frequency module according to claim 11, further comprising:
a sixth circuit component at least partially disposed within the recess.

13. The radio-frequency module according to claim 12, wherein
the sixth circuit component includes the first filter.

14. The radio-frequency module according to claim 13, wherein
the sixth circuit component has
a seventh major surface facing the bottom surface of the recess, and
a third electrode disposed on the seventh major surface.

15. The radio-frequency module according to claim 14, wherein
the first electrode of the first circuit component is electrically coupled to the third electrode of the sixth circuit component, and
the second electrode of the first circuit component is electrically coupled to the second circuit component.

16. The radio-frequency module according to claim 13, wherein
the module substrate includes a via-conductor that connects the first major surface and the second major surface, and
the sixth circuit component is disposed between the first circuit component and the via-conductor in a plan view of the module substrate.

17. The radio-frequency module according to claim 13, further comprising:
a seventh circuit component disposed on the first major surface, the seventh circuit component including the power amplifier, wherein
the module substrate includes a ground electrode layer disposed between the sixth circuit component and the seventh circuit component in a sectional view of the module substrate.

18. The radio-frequency module according to claim 1, wherein
the first circuit component includes a filter coupled to a power amplifier.

19. The radio-frequency module according to claim 1, wherein
the first circuit component includes a switch coupled between a power amplifier and a plurality of filters.

20. A radio-frequency module comprising:
a module substrate having a first major surface and a second major surface that are opposite to each other, the second major surface having a recess;
a first circuit component at least partially disposed within the recess;
an epoxy resin member filling the recess, the epoxy resin member covering at least a portion of the first circuit component;
a resin wiring layer covering the recess, the resin wiring layer having a polyimide resin portion and a wiring portion; and
a second circuit component disposed on the resin wiring layer, the second circuit component being electrically coupled to the first circuit component.
